(19) United States
(12) Patent Application Publication
(10) Pub. No.: US 2024/0421023 A1
(43) Pub. Date: Dec. 19, 2024

(54) ELECTRONIC PACKAGE

(71) Applicant: SILICONWARE PRECISION INDUSTRIES CO., LTD., Taichung City (TW)

(72) Inventors: Chih-Hsien CHIU, Taichung City (TW); Wen-Jung TSAI, Taichung City (TW); Chin-Chiang HE, Taichung City (TW); Wan-Chin CHUNG, Taichung City (TW); Che-Wei YU, Taichung City (TW)

(73) Assignee: SILICONWARE PRECISION INDUSTRIES CO., LTD., Taichung City (TW)

(21) Appl. No.: 18/465,773

(22) Filed: Sep. 12, 2023

(30) Foreign Application Priority Data
Jun. 15, 2023 (TW) 112122425

(51) Int. Cl. H01L 23/367; H01L 23/31

(52) U.S. Cl. CPC H01L 23/367; H01L 23/3128

(57) ABSTRACT

An electronic package is provided, in which an electronic element and a heat dissipation member are disposed on different areas of a carrier structure having a heat dissipation layer, where the electronic element is covered by an encapsulation layer, and the heat dissipation member is thermally connected to the electronic element via the heat dissipation layer, so that the heat energy generated by the electronic element can be prevented from conducting into the encapsulation layer during the heat dissipation process, such that the problem of overheating around the electronic element can be avoided.

### BACKGROUND

### 1. Technical Field

The present disclosure relates to a package structure, and more particularly, to an electronic package with a heat dissipation member.

### 2. Description of Related Art

With the increasing demands of electronic products in function and processing speed, semiconductor chips, which are the core components of electronic products, need to have higher density electronic elements and electronic circuits, so semiconductor chips will generate a greater amount of heat energy during operation. Furthermore, since the conventional encapsulant for encapsulating the semiconductor chip is made of a poor heat transfer material (that is, the heat dissipation efficiency is not good) with a thermal conductivity of only 0.8 W·m⁻¹·k⁻¹, it will cause damage to the semiconductor chip and product reliability issues if the heat generated by the semiconductor chip cannot be effectively dissipated.

Therefore, in order to quickly dissipate heat to the outside, heat sinks or heat spreaders are usually arranged in semiconductor packages in the industry. The heat sink is usually bonded to the back surface of the semiconductor chip by a heat dissipation glue, such as a thermal interface material (TIM), and usually the top surface of the heat sink is exposed from the encapsulant or directly exposed to the atmosphere to dissipate the heat generated by the semiconductor chip via the heat dissipation glue and the heat sink.

As shown in FIG. 1, in the manufacturing method of a conventional semiconductor package 1, a semiconductor chip 11 is first disposed on a package substrate 10 via an active surface 11a thereof by means of flip-chip bonding (that is, via conductive bumps 110 and an underfill 111), then a heat dissipation member 12 is bonded onto an inactive surface 11b of the semiconductor chip 11 via a top sheet 120 thereof through a TIM layer 13, and a supporting leg 121 of the heat dissipation member 12 is erected on the package substrate 10 via an adhesive layer 15. Next, an encapsulation molding operation is carried out, so that an encapsulant 14 covers the semiconductor chip 11 and the heat dissipation member 12, and the top sheet 120 of the heat dissipation member 12 is exposed from the encapsulant 14.

During operation, the heat energy generated by the semiconductor chip 11 is conducted to the top sheet 120 of the heat dissipation member 12 via the inactive surface 11b and the TIM layer 13 to dissipate heat to the outside of the semiconductor package 1. However, in the conventional semiconductor package 1, the heat dissipation

member 12 and the encapsulant 14 are disposed at the same place on the package substrate 10. Therefore, when the heat energy generated by the semiconductor chip 11 is conducted to the heat dissipation member 12, the heat energy will be conducted to the encapsulant 14 via the supporting leg 121, causing the overheating around the semiconductor chip 11 due to the slow heat dissipation of the encapsulant 14. As a result, the semiconductor chip 11 will be damaged due to overheating, resulting in poor reliability of the semiconductor package 1.

Therefore, how to overcome various problems of the above-mentioned prior art has become a difficult problem urgently to be overcome in the industry.

### SUMMARY

In view of the above-mentioned deficiencies in the prior art, the present disclosure provides an electronic package, which comprises: a carrier structure being defined with an encapsulation area and a functional area adjacent to the encapsulation area on one side of the carrier structure; an electronic element disposed on the encapsulation area of the carrier structure and electrically connected to the carrier structure; a heat dissipation member disposed on the functional area of the carrier structure and thermally connected to the electronic element; and an encapsulation layer formed on the encapsulation area of the carrier structure and covering the electronic element, wherein the encapsulation layer is free from being formed on the functional area.

In the aforementioned electronic package, the carrier structure has a heat dissipation layer thermally connected to the electronic element and the heat dissipation member.

In the aforementioned electronic package, a height of the electronic element relative to the carrier structure is equal to a height of the encapsulation layer relative to the carrier structure.

In the aforementioned electronic package, a height of the heat dissipation member relative to the carrier structure is equal to a height of the electronic element relative to the carrier structure.

In the aforementioned electronic package, a height of the heat dissipation member relative to the carrier structure is less than or equal to a height of the encapsulation layer relative to the carrier structure.

In the aforementioned electronic package, the heat dissipation member is flush with a side surface of the carrier structure.

In the aforementioned electronic package, the heat dissipation member protrudes from a side surface of the carrier structure.

In the aforementioned electronic package, the electronic element has a sensible heat area, the carrier structure has a functional pad corresponding to a position of the sensible heat area, and the electronic element is thermally connected to the heat dissipation member via the functional pad.

In the aforementioned electronic package, the present disclosure further comprises at least one electronic module disposed on the functional area and electrically connected to the carrier structure. For example, the electronic module is surrounded by the heat dissipation member.

In the aforementioned electronic package, the present disclosure further comprises a heat dissipation structure disposed on the heat dissipation member.

In the aforementioned electronic package, a plurality of the heat dissipation members are disposed on the carrier structure.

It can be seen from the above that, in the electronic package of the present disclosure, the electronic element and the heat dissipation member are disposed on different areas of the carrier structure, and the heat dissipation member is thermally connected to the electronic element, so that the heat energy generated by the electronic element can be prevented from conducting into the encapsulation layer during the heat dissipation process, such that the problem of overheating around the electronic element can be avoided. Therefore, compared with the prior art, the electronic package of the present disclosure can effectively avoid the problem of overheating during operation, thereby ensuring the reliability of the electronic package.

### BRIEF DESCRIPTION OF THE DRAWINGS

FIG. 1 is a schematic cross-sectional view of a conventional semiconductor package.

FIG. 2A is a schematic cross-sectional view of an electronic package according to the present disclosure.

FIG. 2B is a schematic top view of FIG. 2A.

FIG. 2C and FIG. 2D are schematic top views showing other aspects of FIG. 2A.

FIG. 3 is a schematic cross-sectional view showing another embodiment of FIG. 2A.

FIG. 4A is a schematic cross-sectional view showing yet another embodiment of FIG. 2A.

FIG. 4B is a schematic top view of FIG. 4A.

FIG. 5 is a schematic cross-sectional view showing further embodiment of FIG. 2A.

FIG. 6A and FIG. 6B are schematic cross-sectional views showing other different embodiments of FIG. 4A.

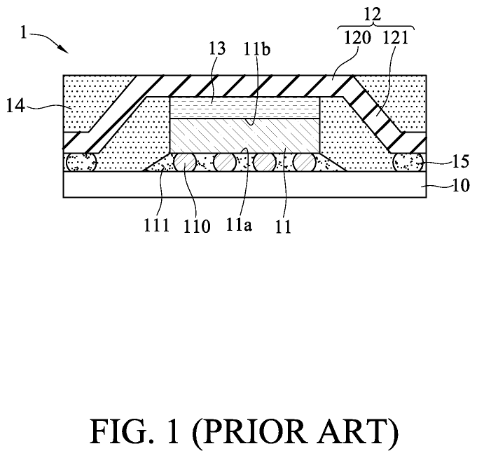

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “upper,” “first,” “second,” “a,” “one” and the like are merely used for clear explanation rather than limiting the practicable scope of the present disclosure, and thus, alterations or adjustments of the relative relationships thereof without essentially altering the technical content should still be considered in the practicable scope of the present disclosure.

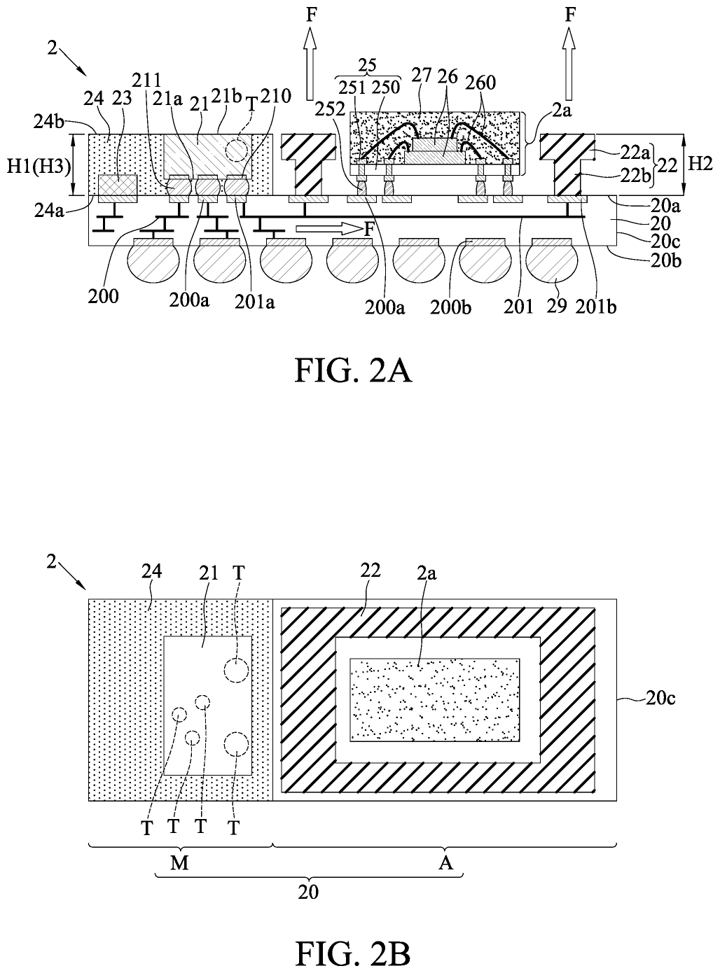

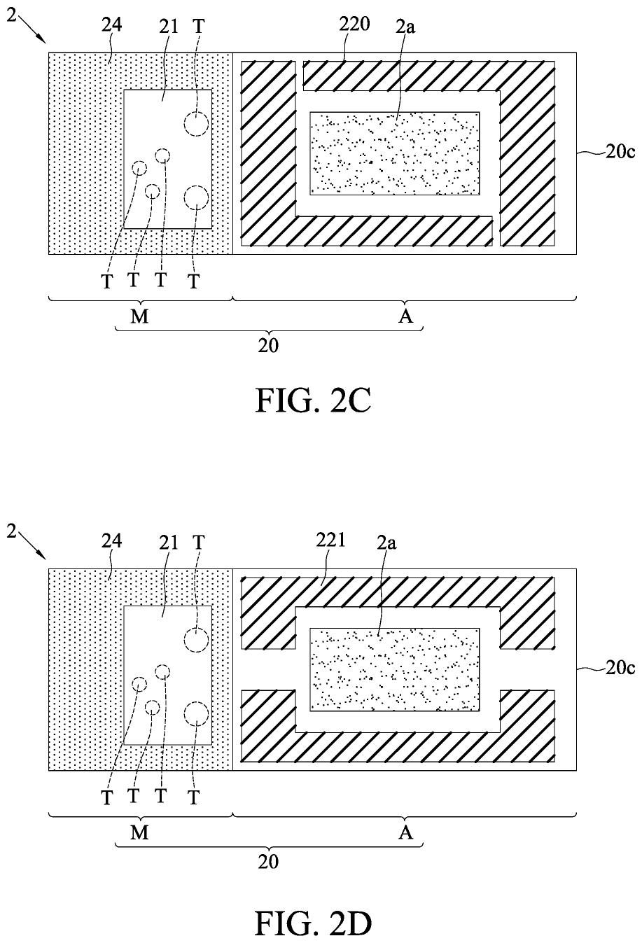

FIG. 2A is a schematic cross-sectional view of an electronic package 2 according to the present disclosure, and FIG. 2B is a schematic top view of the electronic package 2 according to the present disclosure.

As shown in FIG. 2A, the electronic package 2 comprises a carrier structure 20, at least one electronic module 2a disposed on the carrier structure 20, at least one electronic element 21, at least one heat dissipation member 22, and an encapsulation layer 24 covering the electronic element 21.

The carrier structure 20 has a first side 20a and a second side 20b opposing the first side 20a, and the first side 20a is defined with at least one encapsulation area M for laying the encapsulation layer 24 and at least one functional area A adjacent to the encapsulation area M.

In an embodiment, the carrier structure 20 is, for example, a package substrate having a core layer and a circuit structure, a package substrate having a coreless circuit structure, a through-silicon interposer (TSI) having through-silicon vias (TSVs), or other board types, and the carrier structure 20 includes at least one insulating layer and at least one circuit layer 200 (such as at least one fan-out type redistribution layer [RDL]) bonded to the insulating layer. For example, the material for forming the circuit layer 200 is copper, and the material for forming the insulating layer is such as polybenzoxazole (PBO), polyimide (PI), prepreg (PP), or other dielectric materials. It should be understood that the carrier structure 20 may also be other types of chip-carrying board, such as a lead frame, a wafer, or other types of board having metal routings, and the like, and the present disclosure is not limited to as such.

Moreover, the first side 20a of the carrier structure 20 can be used as a chip placement side, so that the circuit layer 200 is formed with a plurality of electrical contact pads 200a, first functional pads 201a and second functional pads 201b formed on and exposed from the first side 20a of the carrier structure 20, and the second side 20b of the carrier structure 20 can be used as a ball placement side, so that the circuit layer 200 is formed with a plurality of ball placement pads 200b formed on and exposed from the second side 20b of the carrier structure 20. For example, the electrical contact pad 200a is located on the encapsulation area M and the functional area A, and the first functional pad 201a is used as a heat dissipation pad and is located on the encapsulation area M, and the second functional pad 201b is used as a heat dissipation pad and is located on the functional area A.

Also, the second side 20b of the carrier structure 20 can be used as a ball placement side, so that a plurality of conductive elements 29 are disposed on the ball placement pads 200b. For example, the conductive element 29 can be a metal pillar such as a copper pillar, a metal bump covered with an insulating block, a solder ball, a solder ball with a copper core ball, or other conductive structures.

In addition, at least one heat dissipation layer 201 connecting the ball placement pad 200b, the first functional pad 201a and the second functional pad 201b is formed in the carrier structure 20. For example, the heat dissipation layer 201 can be manufactured using the same manufacturing process as the circuit layer 200 to simplify the manufacturing of the carrier structure 20.

The electronic module 2a is disposed on the functional area A of the first side 20a of the carrier structure 20 and is electrically connected to the circuit layer 200, wherein the electronic module 2a includes a carrier board 25, at least one semiconductor chip 26 disposed on the carrier board 25 and a cladding layer 27 covering the semiconductor chip 26.

In an embodiment, the carrier board 25 is, for example, a package substrate having a core layer and a circuit structure, a package substrate having a coreless circuit structure, a through-silicon interposer (TSI) having through-silicon vias (TSVs), or other board types, and the carrier board 25 includes at least one dielectric layer 250 and at least one wiring layer 251 (such as at least one fan-out type redistribution layer [RDL]) bonded to the dielectric layer 250. For example, the material for forming the wiring layer 251 is copper, and the material for forming the dielectric layer 250 is such as polybenzoxazole (PBO), polyimide (PI), prepreg (PP), or other dielectric materials. It should be understood that the carrier board 25 may also be other types of chip-carrying board, such as a lead frame, a wafer, or other types of board having metal routings, and the like, and the present disclosure is not limited to as such.

Furthermore, a plurality of the semiconductor chips 26 are stacked on the carrier board 25, and the semiconductor chips 26 are electrically connected to the wiring layer 251 via a plurality of wires 260 in a wire-bonding manner. Alternatively, the semiconductor chip 26 can also be electrically connected to the wiring layer 251 of the carrier board 25 via a plurality of conductive bumps (not shown) in a manner of flip-chip bonding, and the conductive bumps are covered with an underfill (not shown); or, the semiconductor chip 26 can also directly contact the wiring layer 251 of the carrier board 25.

Also, the material for forming the cladding layer 27 is an insulating material, such as polyimide (PI), encapsulant of epoxy resin, or packaging material, and the cladding layer 27 can be formed by molding, lamination, or coating.

In addition, the electronic module 2a is bonded onto the electrical contact pads 200a via the wiring layer 251 of the carrier board 25 thereof through a plurality of conductors 252 to electrically connect the circuit layer 200. For example, the conductor 252 can be a metal pillar such as a copper pillar, a metal bump covered with an insulating block, a solder ball, a solder ball with a copper core ball, or other conductive structures.

It should be understood that the electronic module 2a has various aspects and can be designed according to the requirements of the functional area A, and the present disclosure is not limited to as such.

The electronic element 21 is disposed on the encapsulation area M of the first side 20a of the carrier structure 20 and is electrically connected to the circuit layer 200 and thermally connected to the heat dissipation layer 201, wherein the electronic element 21 is an active element, a passive element, or a combination of the active element and the passive element, and the active element is such as a semiconductor chip, and the passive element is such as a resistor, a capacitor, or an inductor.

In an embodiment, the electronic element 21 is a semiconductor chip and has an active surface 21a and an inactive surface 21b opposing the active surface 21a, and the active surface 21a has a plurality of electrode pads 210 to bond to a plurality of conductive bumps 211 such as solder materials, metal pillars, or others, so that the electronic element 21 is bonded to the electrical contact pads 200a via the plurality of conductive bumps 211 in a manner of flip-chip bonding to electrically connect the circuit layer 200, and the electronic element 21 is bonded to the first functional pad 201a to be thermally connected to the heat dissipation layer 201. For example, the conductive bumps 211 may be covered with an underfill (not shown) or the encapsulation layer 24.

In other embodiments, the electronic element 21 can be connected to the electrical contact pad 200a and the first functional pad 201a by a plurality of bonding wires (not shown) in a wire-bonding manner; or, the electronic element 21 may directly contact the electrical contact pad 200a and the first functional pad 201a.

Furthermore, the electronic element 21 has at least one sensible heat area T. For example, the part of the electronic element 21 that is more likely to generate high temperature during operation is used as the sensible heat area T, and its temperature is higher than that of its surrounding parts, such as the region near the electrode pad 210 at the edge shown in FIG. 2A and/or other parts shown in FIG. 2B.

It should be understood that an electronic element 23 such as a passive element can also be disposed on the encapsulation area M of the carrier structure 20, so that the layout of the element on the encapsulation area M can be designed according to requirements, and the present disclosure is not limited to as such.

The encapsulation layer 24 is formed on the encapsulation area M and is free from being formed on the functional area A, so that the encapsulation layer 24 covers the electronic elements 21, 23 and does not cover the electronic module 2a.

In one embodiment, the material for forming the encapsulation layer 24 is an insulating material, such as polyimide (PI), encapsulant of epoxy resin, or packaging material, and the encapsulation layer 24 can be formed by molding, lamination, or coating.

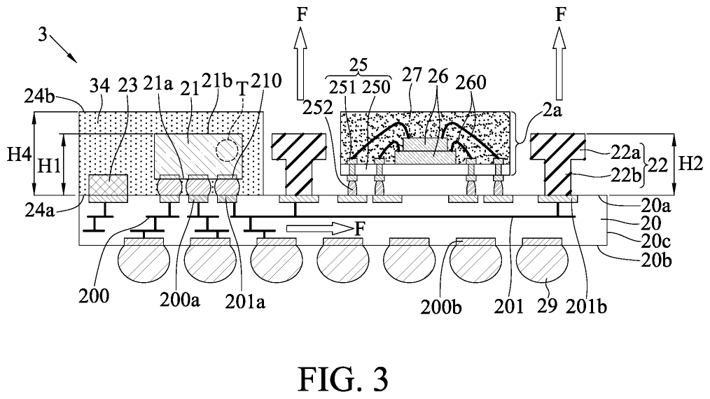

Furthermore, the encapsulation layer 24 has a first surface 24a and a second surface 24b opposing the first surface 24a, wherein the encapsulation layer 24 is bonded to the carrier structure 20 via the first surface 24a, and the electronic element 21 is exposed from the second surface 24b of the encapsulation layer 24. For example, the inactive surface 21b of the electronic element 21 is flush with the second surface 24b of the encapsulation layer 24, so that the inactive surface 21b of the electronic element 21 is exposed from the second surface 24b of the encapsulation layer 24. Alternatively, as shown by an electronic package 3 in FIG. 3, an encapsulation layer 34 can cover the inactive surface 21b of the electronic element 21, so that the electronic element 21 is free from being exposed from the second surface 24b of the encapsulation layer 24.

The heat dissipation member 22 is disposed on the functional area A of the first side 20a of the carrier structure 20 and bonded to the second functional pad 201b.

In one embodiment, the heat dissipation member 22 is a heat conduction wall structure and surrounds the electronic module 2a, and the electronic module 2a is exposed from the heat dissipation member 22. For example, the heat dissipation member 22 is made of metal, such as a continuous copper frame shown in FIG. 2B or a discontinuous copper frame shown by two L-shaped frame bodies 220 in FIG. 2C or two C-shaped frame bodies 221 in FIG. 2D.

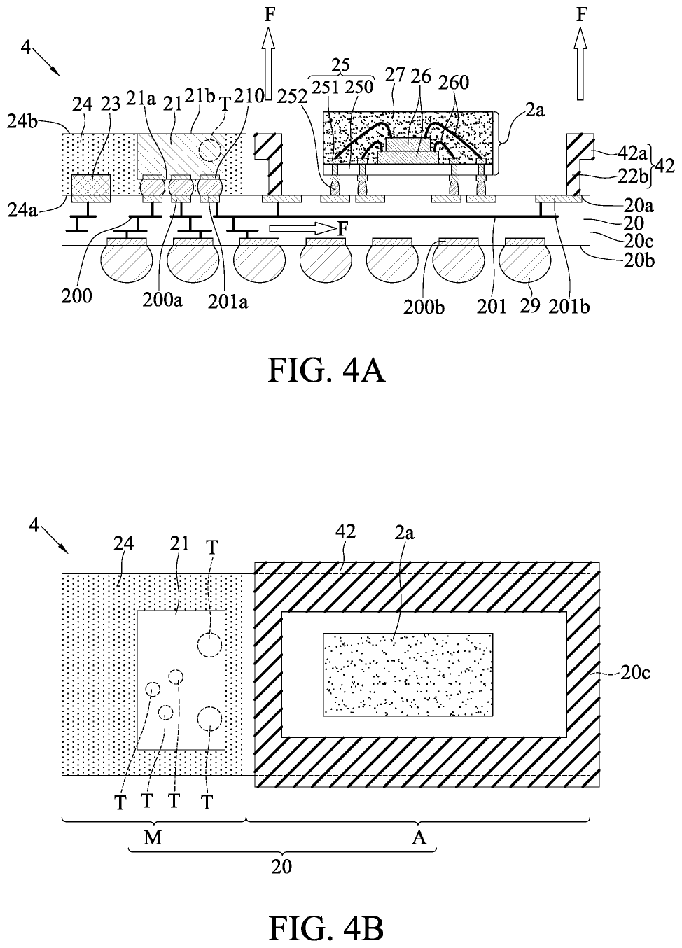

Furthermore, the heat dissipation member 22 has a heat dissipation body 22a and a supporting leg 22b carrying the heat dissipation body 22a and bonded to the second functional pad 201b. For example, the heat dissipation body 22a is in the shape of a boss (e.g., the shape of a protruding platform) and protrudes from the opposite sides of the supporting leg 22b, so that the cross section of the heat dissipation member 22 is T-shaped; alternatively, as shown by an electronic package 4 in FIG. 4A, a heat dissipation body 42a only protrudes from one side of the supporting leg 22b, so that the cross section of a heat dissipation member 42 is inverted L-shaped.

Also, a height H2 of the heat dissipation member 22 relative to the first side 20a of the carrier structure 20 is equal to a height H1 of the electronic element 21 relative to the first side 20a of the carrier structure 20 and/or a height H3 of the encapsulation layer 24 relative to the first side 20a of the carrier structure 20. In another embodiment, such as the electronic package 3 shown in FIG. 3, the height H2 of the heat dissipation member 22 relative to the first side 20a of the carrier structure 20 is lower than a height H4 of the encapsulation layer 34 relative to the first side 20a of the carrier structure 20.

In addition, the heat dissipation body 22a of the heat dissipation member 22 is not protruding from (even flush with) a side surface 20c of the carrier structure 20; alternatively, as shown by the electronic package 4 in FIG. 4A and FIG. 4B, the heat dissipation body 42a of the heat dissipation member 42 protrudes from the side surface 20c of the carrier structure 20.

Therefore, when the electronic package 2, 3, 4 of the present disclosure is in operation, the electronic element 21 conducts the heat energy of the sensible heat area T to the heat dissipation member 22, 42 via a heat conduction path F (as shown in FIG. 2A, FIG. 3, or FIG. 4A) consisting of the first functional pad 201a, the heat dissipation layer 201 and the second functional pad 201b, and then dissipates the heat energy to the outside environment, so that the electronic element 21 can dissipate heat against the sensible heat area T, and thus the electronic package 2, 3, 4 can meet the requirement of high heat dissipation.

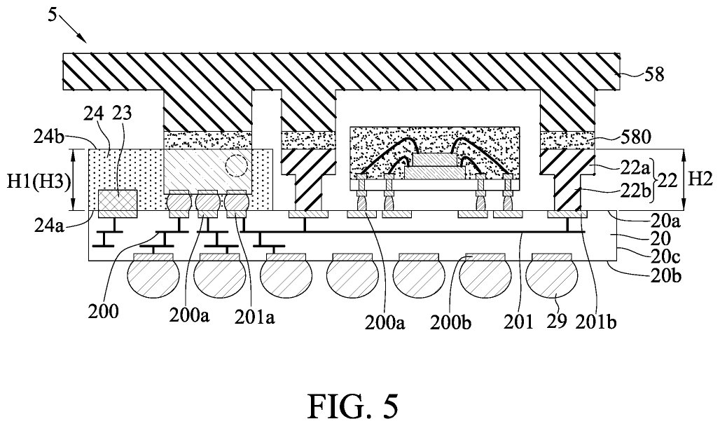

Furthermore, a heat dissipation structure 58 such as a metal cover body can be disposed on the heat dissipation member 22 according to the requirement, such as an electronic package 5 shown in FIG. 5, to improve the heat dissipation effect. For example, the heat dissipation structure 58 is bonded onto the heat dissipation body 22a and the encapsulation layer 24 (even the electronic element 21) via a bonding layer 580 made of such as a thermal interface material (TIM).

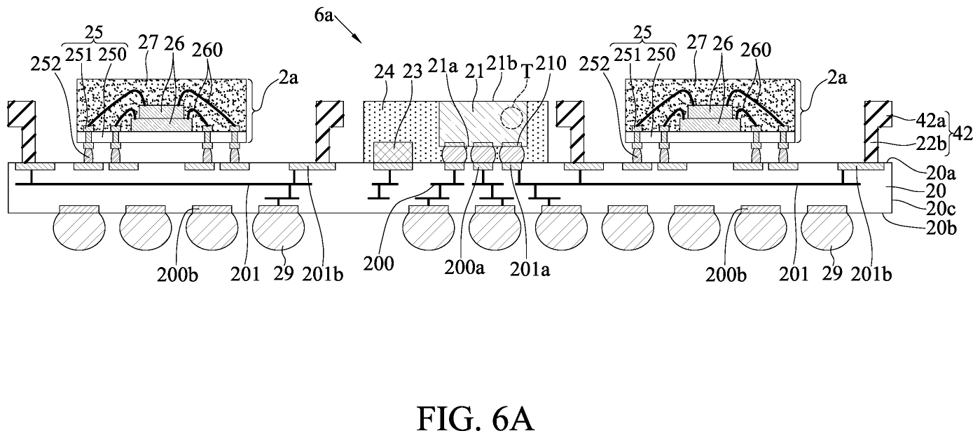

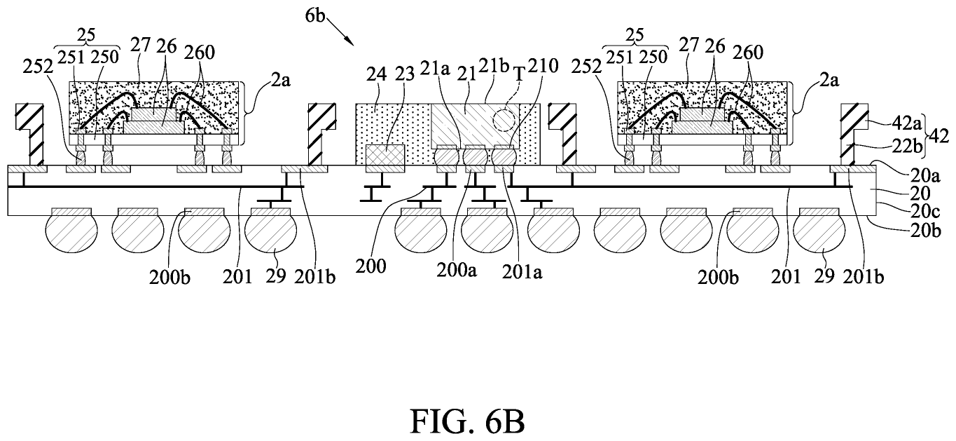

In addition, multiple sets of the heat dissipation members 22, 42 can be configured according to the requirements to accelerate the heat dissipation rate. For example, an electronic package 6a shown in FIG. 6A or an electronic package 6b shown in FIG. 6B is equipped with two sets of the heat dissipation members 42, wherein the heat dissipation body 42a of the heat dissipation member 42 is flush with (as shown in FIG. 6A) or not protruding from (as shown in FIG. 6B) the side surface 20c of the carrier structure 20.

It should be understood that the first functional pad 201a can be configured to correspond to the position of the sensible heat area T of the electronic element 21, so that the first functional pad 201a is connected to the electrode pad 210 closest to the sensible heat area T to accelerate the heat dissipation rate.

To sum up, in the electronic package 2, 3, 4, 5, 6a, 6b of the present disclosure, the electronic element 21 and the heat dissipation member 22, 42 are disposed on different areas of the carrier structure 20, and the heat dissipation member 22, 42 is thermally connected to the electronic element 21, so that the heat energy generated by the electronic element 21 can be prevented from conducting into the encapsulation layer 24 during the heat dissipation process, such that the problem of overheating around the electronic element 21 can be avoided to effectively improve the heat dissipation rate of the electronic package 2, 3, 4, 5, 6a, 6b. Therefore, compared with the prior art, the electronic package 2, 3, 4, 5, 6a, 6b of the present disclosure can effectively avoid the problem of overheating during operation, thereby ensuring the reliability of the electronic package 2, 3, 4, 5, 6a, 6b.

Furthermore, the board surface of the carrier structure 20 is expanded due to the addition of the functional area A, so that warpage is prone to occur due to uneven stress distribution. Therefore, the metal frame is used as the heat dissipation member 22, 42 to disperse the stress of the carrier structure 20 and control the amount of deformation (warpage) of the carrier structure 20, thereby effectively improving the rigidity of the electronic package 2, 3, 4, 5, 6a, 6b. Therefore, the electronic package 2, 3, 4, 5, 6a, 6b of the present disclosure can not only meet the requirements of thinning and increasing the board surface, but also prevent the carrier structure 20 from being excessively warped due to stress concentration at the electronic module 2a or the electronic element 21.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure being defined with an encapsulation area and a functional area adjacent to the encapsulation area on one side of the carrier structure;
an electronic element disposed on the encapsulation area of the carrier structure and electrically connected to the carrier structure;
a heat dissipation member disposed on the functional area of the carrier structure and thermally connected to the electronic element; and
an encapsulation layer formed on the encapsulation area of the carrier structure and covering the electronic element, wherein the encapsulation layer is free from being formed on the functional area.

2. The electronic package of claim 1, wherein the carrier structure has a heat dissipation layer thermally connected to the electronic element and the heat dissipation member.

3. The electronic package of claim 1, wherein a height of the electronic element relative to the carrier structure is equal to a height of the encapsulation layer relative to the carrier structure.

4. The electronic package of claim 1, wherein a height of the heat dissipation member relative to the carrier structure is equal to a height of the electronic element relative to the carrier structure.

5. The electronic package of claim 1, wherein a height of the heat dissipation member relative to the carrier structure is less than or equal to a height of the encapsulation layer relative to the carrier structure.

6. The electronic package of claim 1, wherein the heat dissipation member is flush with a side surface of the carrier structure.

7. The electronic package of claim 1, wherein the heat dissipation member protrudes from a side surface of the carrier structure.

8. The electronic package of claim 1, wherein the electronic element has a sensible heat area, the carrier structure has a functional pad corresponding to a position of the sensible heat area, and the electronic element is thermally connected to the heat dissipation member via the functional pad.

9. The electronic package of claim 1, further comprising at least one electronic module disposed on the functional area and electrically connected to the carrier structure.

10. The electronic package of claim 9, wherein the electronic module is surrounded by the heat dissipation member.

11. The electronic package of claim 1, further comprising a heat dissipation structure disposed on the heat dissipation member.

12. The electronic package of claim 1, wherein a plurality of the heat dissipation members are disposed on the carrier structure.
